(19) United States
(12) Patent Application Publication
(10) Pub. No.: US 2024/0347314 A1
(43) Pub. Date: Oct. 17, 2024

(54) TECHNIQUES FOR ELECTRON ENERGY LOSS SPECTROSCOPY AT HIGH ENERGY

(71) Applicant: FEI Company, Hillsboro, OR (US)

(72) Inventors: Peter Christiaan Tiemeijer, Eindhoven (NL); Sorin Lazar, Eindhoven (NL); Bert Henning Freitag, Weilerswist (DE); Paolo Longo, San Francisco, CA (US)

(21) Appl. No.: 18/299,635

(22) Filed: Apr. 12, 2023

(51) Int. Cl. H01J 37/244

(52) U.S. Cl. CPC H01J 37/244; H01J 2237/1514; H01J 2237/1523; H01J 2237/24485; H01J 2237/2826

(57) ABSTRACT

Systems, devices, methods, and techniques for energy-loss spectroscopy at relatively large energy losses are described. A charged particle microscope system can include a beam column section. The beam column section can include one or more charged particle optical elements calibrated for a first energy and one or more charged particle optical elements calibrated for a second energy. The charged particle microscope system can include a detector section. The detector section can be disposed at a position downstream of the beam column section. The detector section can include an electrostatic or magnetic prism and one or more charged particle optical elements calibrated for the second energy. The first energy and the second energy can be different.

### TECHNICAL FIELD

Embodiments of the present disclosure are directed to charged particle microscope systems, as well as algorithms and methods for their operation. In particular, some embodiments are directed toward techniques for electron energy loss spectroscopy.

### BACKGROUND

Electron energy loss spectroscopy (EELS) describes techniques whereby information about the electronic structure of a material sample can be derived by passing a beam of electrons through the sample, scattering a portion of the electrons. EELS spectrometers operate by collecting inelastically scattered electrons downstream of the sample, relative to the position of a source of electrons, and dispersing these electrons spatially by the energy lost in the inelastic scattering. The spatially dispersed electrons impinge on a detector that generates an EELS spectrum. A challenge with EELS is that the scattering cross section rapidly decreases with increasing energy loss, leading to signal-to-noise limitations for excitations above about 2 keV.

In contrast to other techniques that offer similar spectral data, such as synchrotrons, EELS spectrometers configured to operate as part of charged particle microscope systems are calibrated for a single energy of a beam of electrons, namely the energy of the primary beam of the charged particle microscope. As such, EELS spectrometers are constrained to a relatively narrow energy range about a “zero loss peak” or ZLP that corresponds to the primary beam energy. Inelastic collisions that include energy transfers greater than about 2% of the primary beam energy (e.g., greater than about 4 keV for a 200 keV primary beam), such as inner-shell ionizations and other relatively high energy interactions between the beam of electrons and the sample, suffer from detection limits as a result of poor signal-to-noise, introduced aberration artifacts, and are generally outside the range of typical EELS spectrometers. Synchrotron systems are typically used to generate such data, using beam lines for tender X-rays or hard X-rays, at significantly lower spatial resolution, higher complexity, and expense. There is a need, therefore, for techniques and systems for probing inner-shell and other relatively high energy transitions of a material sample using EELS systems in a charged particle microscope.

### SUMMARY

Systems, devices, methods, algorithms, and techniques for energy-loss spectroscopy at relatively large energy losses are described. In an aspect, a charged particle microscope system can include a beam column section. The beam column section can include one or more charged particle optical elements calibrated for a first energy and one or more charged particle optical elements calibrated for a second energy. The charged particle microscope system can include a detector section. The detector section can be disposed at a position downstream of the beam column section. The detector section can include an electrostatic or magnetic prism and one or more charged particle optical elements calibrated for the second energy. The first energy and the second energy can be different.

In some aspects, the beam column section further includes a sample section. The one or more charged particle optical elements calibrated for the first energy can be upstream of a sample disposed in the sample section, relative to a charged particle source. The one or more charged particle optical elements of the beam column calibrated for the second energy can be disposed downstream of the sample section. The sample section can include an objective lens. the sample can be immersed in an objective field of the objective lens.

In some aspects the detector section includes an EELS spectrometer, calibrated to detect charged particles having an energy about the second energy, based at least in part on energy transfer with inner shell electrons in a sample.

In some aspects, a difference between the first energy and the second energy is from about 2 keV to about 50 keV. The second energy can be from about 90% to about 97.5% of the first energy. In some aspects, the first energy and the second energy are related by the expression A=|(ΔE+E2−E1)/E2|, where ΔE is the energy loss associated with an edge (keV), E1 is the first energy (keV), and E2 is the second energy (keV). The expression A can be less than or equal to about 5%. In some aspects, the first energy is about 300 keV and the second energy is from about 270 keV to about 295 keV.

In some aspects, the charged particle microscope system further includes control circuitry, operably coupled with the beam column section and the detector section and one or more non-transitory machine-readable storage media, storing machine executable instructions that, when executed by the control circuitry, cause the charged particle microscope system to perform operations. The operations can include generating a beam of charged particles at the first energy and generating detector data using the detector section. The detector data describing charged particles at about the second energy.

In some aspects, a calibration scheme for the first energy includes a first set of operating parameters and a calibration scheme for the second energy comprises a second set of operating parameters. The first set of operating parameters and the second set of operating parameters can be related by a scaling factor based at least in part on the energy dependence of refractive effects of the optical elements calibrated for the second energy.

In another aspect, one or more non-transitory machine-readable storage media storing instructions that, when executed by a machine, cause the machine to perform operations. The operations can include recalibrating one or more charged particle optical elements of a charged particle microscope system from a first energy to a second energy, such that the charged particle microscope system includes the beam column section of the preceding aspects.

In some aspects, the operations further include generating a beam of charged particles at the first energy and generating detector data using the detector section. The detector data can describe charged particles at about the second energy. The detector data can include electron energy loss spectrum (EELS) data. The operations can further include determining an interatomic spacing parameter of a sample using the detector data.

In some aspects, recalibrating the one or more charged particle optical elements calibrated from the first energy to the second energy includes measuring the collection angle of the EELS spectrometer or centering the beam with respect to the EELS spectrometer.

In some aspects, the operations further include recalibrating the charged particle optical elements calibrated for the first energy from the first energy to the second energy. The operations can further include generating a beam of charged particles at the second energy. The operations can also further include generating detector data using the detector section, where the detector data can describe charged particles at about the second energy. The operations can further include receiving user interaction data via an interactive user interface. The interaction data can correspond to an action by a user to initiate recalibration of the one or more elements of the charged particle microscope system. The operations can further include generating user interface data configured to modify a display being operably coupled with the charged particle microscope system to present the interactive user interface.

Embodiments of the present disclosure also include systems, components, and methods in accordance with the preceding aspects. The terms and expressions which have been employed are used as terms of description and not of limitation, and there is no intention in the use of such terms and expressions of excluding any equivalents of the features shown and described or portions thereof, but it is recognized that various modifications are possible within the scope of the claimed subject matter. Thus, it should be understood that although the present claimed subject matter has been specifically disclosed by embodiments and optional features, modification and variation of the concepts herein disclosed can be resorted to by those skilled in the art, and that such modifications and variations are considered to be within the scope of this disclosure as defined by the appended claims.

### DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram illustrating an example charged particle microscope system, in accordance with some embodiments of the present disclosure.

FIG. 2 is a schematic diagram illustrating principles of operation of the example charged particle microscope system of FIG. 1, in accordance with some embodiments of the present disclosure.

FIG. 3 is a block diagram illustrating an example process for generating detector data, in accordance with some embodiments of the present disclosure.

FIG. 4A is a graph illustrating example electron energy loss spectrum (EELS) data and Extended X-ray Absorption Fine-Structure (EXAFS) data for a molybdenum foil sample, in accordance with some embodiments of the present disclosure.

FIG. 4B is a graph illustrating example electron energy loss spectrum (EELS) data for an antimony (Sb) sample, in accordance with some embodiments of the present disclosure.

FIG. 5 is a graph illustrating example electron dose data for different material samples used to collect EELS data for embodiments of the present disclosure and comparative techniques of the present art.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While illustrative embodiments have been illustrated and described, it will be appreciated that various changes can be made therein without departing from the spirit and scope of the disclosure. In the forthcoming paragraphs, embodiments of a charged particle microscope system, components, and methods for electron energy loss spectroscopy (EELS) are described. Embodiments of the present disclosure focus on sample microanalysis using EELS-equipped transmission electron microscope (TEM) systems in the interest of simplicity of description. Embodiments are not limited to such systems, but rather are contemplated for systems where analysis of inelastic collisions between a beam of charged particles and atoms of a sample can be complicated by the internal configuration of charged particle optical components. In an illustrative example, scanning electron microscope (SEM) systems can be used for EELS analysis in scanning-transmission (STEM-in-SEM) modes. Similarly, systems can be configured specifically for EELS techniques, omitting typical components of TEM systems adapted for imaging, x-ray microanalysis, or the like. As such, while embodiments of the present disclosure focus on TEM platforms equipped with systems for generating and processing EELS data, additional and/or alternative systems and approaches are contemplated.

Embodiments of the present disclosure include systems, methods, algorithms, and non-transitory media storing computer-readable instructions for electron energy loss spectroscopy (EELS) at relatively high energy losses. In an illustrative example, a charged particle microscope system can include a beam column section including one or more charged particle optical elements calibrated for a first energy and one or more charged particle optical elements calibrated for a second energy. The system can also include a detector section, disposed at a position downstream of the beam column section and comprising an electrostatic or a magnetic prism and one or more charged particle optical elements calibrated for the second energy, where the first energy and the second energy are different. Advantageously, embodiments of the present disclosure improve performance of energy loss spectrometry systems when measuring scattered particles having an energy loss greater than about 3 keV, thereby reducing reliance on synchrotron systems for generating comparable data.

In comparison to charged particle microscopes, synchrotron systems are complex, large. Techniques presented herein permit charged particle microscope systems to generate detector data comparable to x-ray absorption spectroscopy (XAS), specifically its sub-techniques x-ray absorption near-edge spectroscopy (XANES) and extended x-ray absorption fine-structure spectroscopy (EXAFS), using existing EELS detector systems. As an additional advantage, EELS in scanning transmission electron microscopes (STEM) generally provides significantly improved spatial resolution (e.g., on the order of 103-fold greater spatial resolution). Improvements to spatial resolution at such scales significantly increase the depth of information available from nanostructured samples that can vary chemically and structurally over length scales that would be integrated by synchrotron analysis that operates on μm to mm scales.

The following detailed description focuses on embodiments of transmission electron microscope systems, but it is contemplated that additional and/or alternative instrument systems can be improved through the use of the techniques described. Instrument systems can include other charged particle systems including, but not limited to, focused ion-beam systems, scanning electron microscope systems, ion-electron dual-beam systems, or the like.

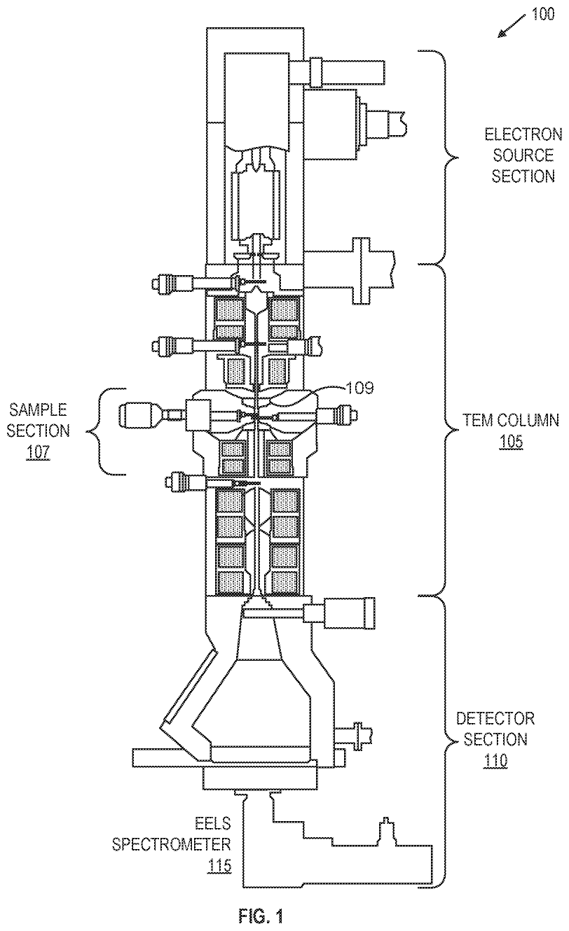

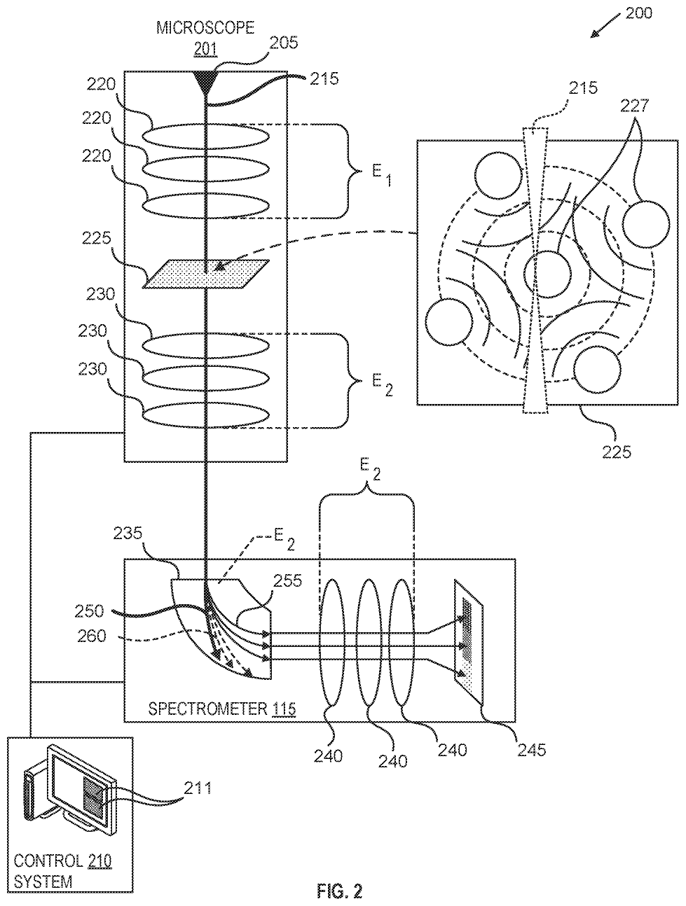

FIG. 1 is a schematic diagram illustrating an example charge particle microscope system 100, in accordance with some embodiments of the present disclosure. In the following description, details of internal components and functions of the example TEM system 100 are omitted for simplicity and to focus description on embodiments of the present disclosure, as described in more detail in reference to FIGS. 2-5, and on techniques for augmenting sample information in spectra including relatively strong background information. The example TEM system 100 includes an electron source section, a TEM column 105 including an sample section 107, and a detector section 110. The present disclosure focuses on techniques for improving the performance of the detector section 110, with attention paid to embodiments of the present disclosure that include one or more electron energy loss spectroscopy (EELS) spectrometers 115.

In brief, the electron source section includes electronics configured to energize an source of charged particles 205 (in reference to FIG. 2), which can include a high-voltage field-emission source or other sources of emitted electrons, such that a beam of electrons is formed and conducted through a vacuum into the TEM column 105. The TEM column 105 includes components for beam forming, including electromagnetic lenses and/or electrostatic lenses, and multiple apertures to control properties of the beam of electrons. TEM column 105 components include condenser lenses, objective lenses, projector lenses, aberration correctors, deflectors, stigmators, among others, as well as corresponding apertures. The sample section 107 hosts a sample 225 (in reference to FIG. 2) through which the beam of electrons can be transmitted. In the case of EELS microanalysis, the beam can be focused onto the sample for spot mode analysis (e.g., through the action of one or more objective lenses) or the beam can be passed through the sample in parallel illumination mode (or at least partially defocused) to gather data from a relatively large sample area.

In some embodiments, the sample section 107 includes an objective lens 109 such that the sample is immersed in an objective field of the objective lens. Advantageously, disposing the sample in the objective field of the objective lens can provide a resolution for STEM mode operation as good as about 0.05 nm. In this context, immersion in the objective field refers to disposing the sample in the magnetic field of the objective lens that extends into the space between the sample and a pole piece of the objective lens. Such immersion significantly reduces possible aberrations of the objective lens, which otherwise would reduce the spatial resolution of the microscope.

In some embodiments, charged particle microscope system 100 operates in field-free STEM mode 100, where the objective lens is not used to focus charged particles onto the sample. In some systems, a mini-condenser lens upstream of the specimen can act as probe-forming lens and a Lorentz lens downstream of the specimen can act as a first imaging lens to provide at least some of the functions of the objective lens. In field-free STEM mode, detector data can be generated at a spatial resolution of about 0.5 nm. While an order of magnitude lower than the immersion case, field-free STEM mode offers significantly improved spatial resolution when compared to synchrotron-based techniques.

A state-of-the-art TEM column can have as many as four condenser lenses for flexible (e.g., step-wise or graduated) demagnification and concentration of the electron beam on the sample, and as many as five projector lenses for flexible magnification of the electron beam downstream of the sample to the detectors, and as many as two aberration correctors. Since a state-of-the-art aberration corrector can comprise additional lenses and several multipoles (e.g., four lenses and two-three or more multipoles), a modern TEM column can include up to about twenty lenses. Coordinated operation of the ensemble of lenses and other optical elements results in a given demagnification at the sample and magnification at the detector. A lack of coordination, in contrast, results in aberrations based at least in part on the electron beam travelling out-of-center through one or more optical elements, the beam having too large beam diameter in one or more lenses, or other issues that reduce system performance. In the context of the present disclosure, “calibration” of charged particle optical elements refers to a set of operating parameters for an ensemble of elements for which excitation parameters are set and verified to give the desired beam properties at the sample (e.g., probe diameter, current, position) and the desired beam properties at the detector (e.g., magnification, focus, position). As would be understood by a person of ordinary skill in the relevant art, calibration of the ensemble of optical elements is typically a complex and laborious task that can occupy several days or weeks of work by an experienced engineer. For this reason, TEM columns are typically supplied with calibration settings for a limited number (e.g., two to five) energies of the electron beam (e.g., 300 keV. 200 keV, 60 keV).

The optical strengths of lenses and multipoles depend on the energy of the electron in the beam and therefore a calibration is specific to electrons with energy equal to or close to the energy for which the calibration settings have been set and verified. For example, in a TEM that is operating with a beam energy of 300 keV, charged particle optical elements of the TEM column that are calibrated for electrons having energies of 300 keV will introduce various aberrations into the beam. In this example, an electron having an energy that deviates from 300 keV by as little as 10 eV, a deviation of about 0.003%, will be focused onto a plane that is shifted away from the intended sample plane by a distance of about 100 nm. The chromatic aberration of the objective lens, in this example, significantly impairs the spatial resolution of the microscope. For this reason, in a typical calibration scheme, every element or nearly every element is calibrated for the same beam energy. For example, demagnification elements and magnification elements are calibrated for the same beam energy.

The detector section 110 includes one or more types of detector, sensor, screen, and/or optics configured to generate images, spectra, and other data for use in sample imaging and/or microanalysis. For example, the imaging section can include a scintillator screen, binoculars, transmission electron microscopy (TEM) detector(s) (e.g., pixelated electron detector, secondary electron detector, camera(s), and electron energy loss spectroscopy (EELS) spectrometer(s) 115, among others. The EELS spectrometer 115 functions as an energy filter at least in part by focusing the beam of electrons onto an electrostatic or magnetic dispersive element (also referred to as a “prism”) that applies a force on an electron that is proportional to the velocity of the electron. In this way, electrons that have transferred energy to the sample (e.g., by inelastic collision(s)) can be redirected through the magnetic dispersive element and toward a detector. The detector can include a pixelated detector (e.g., a CCD device configured to detect electrons) that generates one or two dimensional EELS data, from which EELS spectra can be derived. In some embodiments, EELS spectrometer(s) 115 also include one or more optical elements, such as electromagnetic or electrostatic lenses and/or multipoles and/or accelerators, to condition and/or focus the scattered electrons onto the detector.

FIG. 2 is a schematic diagram illustrating principles of operation of an example charged particle microscope system 200, in accordance with some embodiments of the present disclosure. The example system 200 is an example of the charged particle microscope 100 of FIG. 1, and includes a microscope 201, corresponding to the source section, the TEM column 105, the sample section 107 and, in some cases, part of the detector section 110 of charged particle microscope 100. The example system 200 also includes the spectrometer 115, in the illustrated embodiment represented by components of an EELS spectrometer. The example system 200 also includes elements of a control system 210, being operably coupled with the microscope 201 and the spectrometer 115.

The microscope 201 can include a source of charged particles 205 configured to generate a beam of charged particles 215 (e.g., electrons or ions) of a first energy E1. A fraction of particles can be scattered by the sample. The scattering events can include inelastic scattering. In the technique of electron energy loss spectroscopy (EELS), an EELS spectrometer 115 can be used to measure the energies of inelastically scattered electrons, from which an energy loss ΔE can be derived, associated with inelastic scattering events. An electron that has lost energy during an inelastic scattering event travels through the TEM column and through the EELS spectrometer at an energy of E1−ΔE. The magnitude of the deviation from the energy E1 for which the TEM column and EELS spectrometer have been calibrated influences the performance of the charged particle optical elements through which the electron travels between the sample and a detector of the EELs spectrometer 115. The deviation ΔE from the calibration energy causes the charged particle optical elements to deviate from their respective calibrated optical strengths, resulting in impaired imaging performance.

For example, where ΔE includes a range of energy-loss values, a number of imaging planes can be defined by the energy-dependent performance of charged particle optical elements. While a portion of the scattered electrons can be focused onto the detector, in line with the calibration of the system, some electrons can be focused onto image planes at positions upstream of the detector, downstream of the detector, or at positions away from the entrance of the spectrometer (e.g., off axis). In some cases, scattered electrons can be steered into contact with internal surfaces of the TEM column or the spectrometer, thereby being eliminated from the EELS signal entirely.

For calibration schemes described above, it is possible to detect electrons having energies that deviate from the calibrated energy by as much as ΔE/E1≈2%, provided the lens settings of the column are carefully chosen and provided that multipole settings in the spectrometer are carefully chosen. That being said, for values of ΔE larger than approximately 2% of the calibration energy E1 (i.e., ΔE/E1>˜2%), the calibration schemes described above fail to direct scattered electrons through the charged particle optical elements of the TEM column and through those of the EELS spectrometer without introducing artifacts (e.g., over/under magnification and/or deviations from the beam position). Deviations in the magnification and position of the beam results in inefficient collection of scattered electrons by the EELS spectrometer. Further, aberrations that exclude a portion of scattered electrons from detector signals impair the usefulness of recorded EELS spectra for properly and reliably quantifying the elemental composition of the sample.

In embodiments of the present disclosure, electrons deviating from the beam energy (E1) by equal to or more than about 2% (e.g., ΔE/E1≥˜2%) can be efficiently collected by employing a different calibration scheme to those described above, for which a second calibration energy E2 is used for one or more charged particle optical elements downstream of the sample. Generally, according to the present disclosure, one or more charged particle optical elements 220 are calibrated for a first energy E1 and one or more charged particle optical elements 230 are calibrated for a second energy E2. In some embodiments, the optical element(s) 220 calibrated for the first energy E1 is/are upstream of a sample 225 disposed in an sample section (e.g., sample section 107 of FIG. 1) and the optical element(s) 230 calibrated for the second energy E2 is/are downstream of the sample 225. The first energy E1 and the second energy E2 can be different, for example, E1 can be greater than E2. Electrons having an energy about the first energy E1 upstream of the specimen that lose energy (ΔE) by scattering will have an energy about E1−ΔE downstream of the specimen. To that end, E2 can be selected such that E2 is equal to about E1−ΔE. In some embodiments, E2 can be determined using the absolute value expression: |(ΔE+E2−E1)/E2|≤about A, where A is a value from about 1% to about 10%, including subranges, fractions, and interpolations thereof. For example A can be equal to about 1%, about 2%, about 3%, about 4%, about 5%, about 6%, about 7%, about 8%, about 9%, or about 10%.

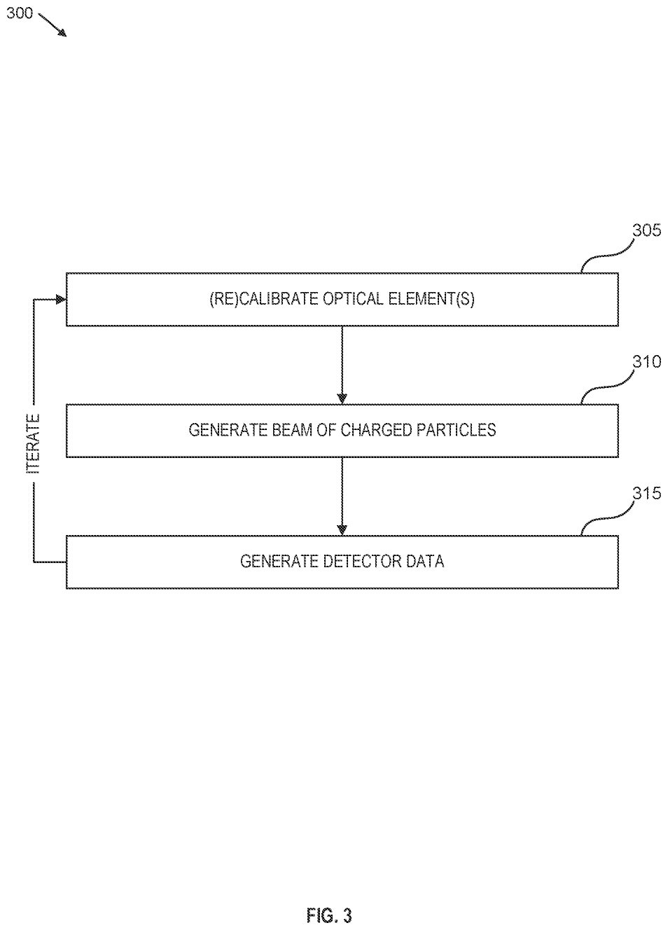

In the illustrative examples of FIGS. 3-5, the difference between E1 and E2 can be from about 2 keV to about 50 keV, including subranges, fractions, and interpolations thereof. For example, the difference between E1 and E2 can be from about 2 keV to about 35 keV, from about 2 keV to about 10 keV, about 10 keV, about 20 keV, about 30 keV, or the like. The energies E1 and E2 can be from about 50 keV to about 500 keV, including subranges, fractions, and interpolations thereof. In an illustrative example, E1 can be about 300 keV and E2 can be about 290 keV. In another example E1 can be about 310 keV and E2 can be about 300 keV. In another example, E1 can be about 200 keV and E2 can be about 190 keV. The cross section for a given excitation (e.g., an inner-shell ionization) can depend at least in part on E1. To that end, for values of E1 outside the stated range, high-energy loss data can be dominated by noise, based at least in part on the relatively low probability of a charged particle to induce the given excitation.

A difference between the first energy and the second energy can depend at least in part on the value of the first energy. For example, the second energy can be a fraction of the first energy. In some embodiments, the second energy can be from about 60% to about 99% of the first energy, including subranges, fractions, and interpolations thereof. In an illustrative example, the second energy can be from about 90% to about 97.5% of the first energy. The difference between the first and second energy can be chosen to be equal or approximately equal to the energy loss that is to be recorded by the EELS spectrometer. The techniques described herein permit charged particle microscopes to interrogate energy ranges corresponding to relatively high energy losses, where a larger difference between E1 and E2 will result in detector data (e.g., extended energy loss fine structure, or EXELFS) that corresponds to an excitation energy of a scattering event of about the value of the difference. In this way, a difference of about 10 keV can provide detector data for scattering events having an excitation energy of about 10 keV.

In EXELFS, the fine structure in the energy-dependence of the probabilities of core-shell excitation is studied. The total number of electrons Not that experience an energy loss due to the excitation of a core-shell scales approximately with the energy loss to the power −1.5, that is, Nₜₒₜ ∝ΔE^{-1.5}. In this way, the number of scattered electrons can be distributed over a range ΔEₜₐᵢₗ of energies (known as the ‘tail of the edge’) and over a range Δϑ of scattering energies (known as the ‘scattering distribution’). The length of the tail is approximately 20% of the energy loss (ΔEₜₐᵢₗ≈0.2ΔE). The range of scattering angles is roughly equal to Δϑₘₑₐₙ=ΔE/2/E1. When these expressions are combined, it can be estimated that the number of energy-lost electrons in a specific energy interval dE and in a specific solid angle dΩ=(dϑ)² scales with the energy loss as described in the expression:

$${N}_{tot} \cdot dE \cdot d Ω ∝ Δ {E}^{- 1.5} \cdot ( dE / Δ {E}_{tail} ) \cdot {( d ϑ / {Δϑ}_{mean} )}^{2} ∝ Δ {E}^{- 3.5}$$

This estimate shows that the EXELFS signal in an EELS spectrometer rapidly drops with increasing energy loss. For example, in order to reach the same number of counts (and hence the same statistics) in the EXELFS region (100 eV wide) for the K-shell edges in titanium (5.0 keV), copper (9.0 keV), molybdenum (ΔE=20 keV), and antimony (ΔE=30.5 keV), the required beam dose scales (relative to Ti) by the ratios of 1:8:128:560. In this way, collection solid angle of the EELS spectrometer can determine to a large part the performance of a TEM system in measuring EXELFS spectra. Advantageously, collection solid angle improves significantly when the TEM column is calibrated to better collect scattered electrons in accordance with the expression |(ΔE+E2−E1)/E2|<˜2%. In this way, calibration processes of the present disclosure can include measuring the collection angle and centering the beam with respect to the EELS spectrometer. With respect to edge position or edge structure, noise can become more significant at larger values of the difference between E1 and E2, such that beyond about ΔE=30 keV, integration time and total electron dose can be limited, for example, by sample sensitivity.

The spectrometer 115 can include charged particle optical elements, such as a dispersive element 235 and one or more electromagnetic and/or electrostatic elements 240 (e.g., lenses, accelerators, quadrupoles, hexapoles, octupoles, etc.). The dispersive element 235 can comprise one or more magnetic and/or electrostatic dispersive elements (also referred to as a “prisms”). The spectrometer 115 can be post-column (located after the TEM column as in FIG. 2) or it can be in-column, operably coupled with the TEM column. The elements 235 and 240 can be calibrated for the second energy E2. In reference to the dispersive element 235, calibration for the second energy E2 refers to the operation of the dispersive element 235 to disperse charged particles (e.g., electrons) having an energy that deviates from E2 by not more than about 2% of E2. In this way, charged particles having an energy of about E2 can be transmitted to elements 240 and subsequently directed to a detector 245 of the spectrometer 115. In some embodiments, the elements 240 also focus the charged particles onto the detector 245.

Other components of the system 200 can serve to attenuate, redirect, absorb, or otherwise exclude from detector data, unscattered 250 or weakly scattered charged particles 255 (e.g., electrons that transit the sample 225 without scattering). For example, element(s) 230 can apply a force to electrons that is proportional to the energy of the electrons (e.g., a magnetic force), which redirects electrons having an energy of about E1 away from a beam axis and into an absorber material or other surface internal to the microscope 201.

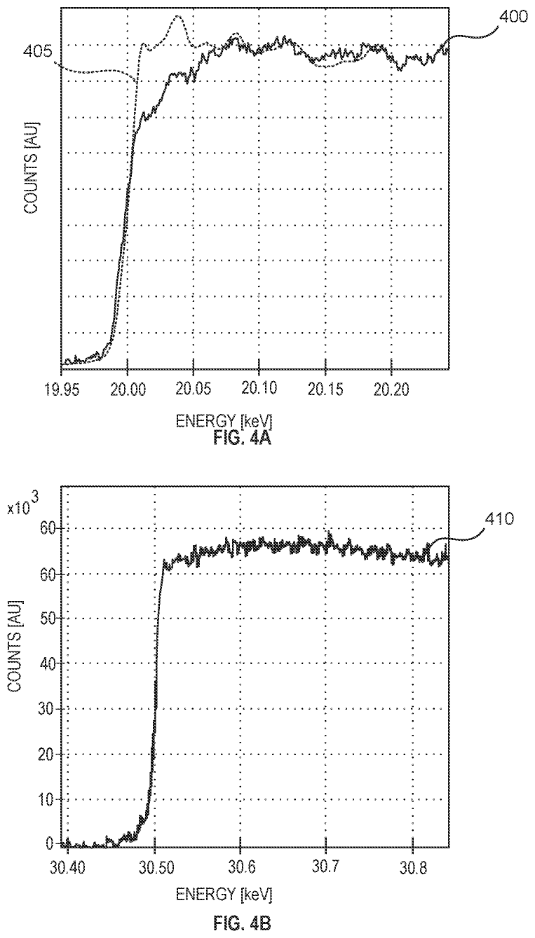

The detector 245 can generate detector data. As described in more detail in reference to FIGS. 3-5, detector data can include EELS spectra resulting from interactions between the beam of charged particles 215 and atoms 227 of the sample 225. For example, where the microscope 201 is operating in STEM mode (e.g., scanning TEM or STEM-in-SEM) and the sample 225 is thinned to permit the transmission of the beam, a beam of electrons can focus onto a point in the sample 225 that permits the measurement of single atoms or groups of atoms on a nanometer scale. As described in more detail in reference to FIGS. 4A-4B, interactions between neighboring atoms 227 can introduce fine structure into detector data. In this way, detector data can be used to derive chemical, physical, and/or structural information about the atoms 227 (e.g., oxidation state, coordination information, etc.). Advantageously, embodiments of the present disclosure combine fine-structure information with spatial localization, which is unavailable in typical synchrotron systems used for generating comparable detector data. In a TEM operating in STEM mode, atomic scale resolution can be obtained by focusing the beam of charged particles 215, permitting the system 200 to be used to generate nanometer-scale maps of material properties of the sample 225.

The control system 210 can include one or more machines (e.g., computing devices) that are operably coupled with control circuitry disposed in the microscope 201 and/or the spectrometer 115. In an illustrative example, control circuitry can include an arrangement of circuit components connected to a power source and configured to control the application of power (e.g., voltage and or current) to the source 205, the elements 220, 230, 235, 240, and/or the detector 245. In this way, processes for calibrating and/or recalibrating the elements 220, 230, 235, 240, and/or the detector 245 can be orchestrated by the control system 210, in accordance with one or more operations encoded in machine-executable instructions stored on one or more machine-readable storage media (e.g., local storage media, distributed “cloud” storage media, etc.). The one or more machines can include, but are not limited to, personal computers, laptops, tablets, servers, application specific machines (ASMs), or the like. In some embodiments, the control system 210 includes user-interactable elements, such as a display and input peripherals (e.g., mouse and keyboard), through which a user can reversibly implement a high-energy-loss EELS mode, in accordance with the operations described in reference to FIG. 3. In an illustrative example, a user can select an interactive graphical element 211 on a user interface (e.g., in an application, browser environment, etc.) that initiates the high-energy-loss EELS mode. To return the system 200 to its prior state, the user can select an interactive graphical element 211 that initiates a calibration of the elements back 220, 230, 235, and/or 240 from E1 or E2 back to the prior calibration energy (e.g., the first energy E1, the second energy E2, or a third energy E3).

To that end, processes of the present disclosure (e.g., example process 300 of FIG. 3) can include operations for receiving user interaction data (e.g., via an interactive user interface), where the interaction data corresponds to an action by a user to initiate or reverse a recalibration of one or more elements of the charged particle microscope system. Similarly, the processes of the present disclosure can include generating user interface data configured to modify a display (e.g., of control system 210) to present an interactive user interface.

FIG. 3 is a block diagram illustrating an example process 300 for generating detector data, in accordance with some embodiments of the present disclosure. One or more operations of the example process 300 may be executed by a computer system in communication with additional systems including, but not limited to, characterization systems, network infrastructure, databases, and user interface devices. In some embodiments, at least a subset of the operations described in reference to FIG. 3 are performed automatically (e.g., without human involvement) or pseudo-automatically (e.g., with human initiation or limited human intervention). In an illustrative example, operations for generating and shaping a beam of electrons can be executed automatically, with the TEM system 100 being configured to maintain properties of the beam of electrons at or about a set point that can be designated by a human user. In another illustrative example, a human user can initiate an EELS mode using the techniques described herein by activating a subsystem of the charged particle microscope 100 (e.g., through an interactive user environment presented through a user terminal, such as a browser or software application, and/or a push-button control panel) that initiates recalibration of the charged particle microscope 100 from imaging mode or conventional EELS mode to high-loss mode. To that end, while example process 300 is described as a sequence of operations, it is understood that at least some of the operations can be omitted, repeated, and/or reordered. In some embodiments, additional operations precede and/or follow the operations of example process 300 that are omitted for clarity of explanation, for example, operations for calibration of the electron source, alignment and aberration correction of the beam of electrons, or the like.

At operation 305, example process 300 includes calibrating and/or recalibrating charged particle optical elements. Elements 220, 230, 235, and 240 of FIG. 2 are examples of the charged particle optical elements of operation 305. In general, calibrating and recalibrating can include one or more sub-operations including modifying electronic parameter(s) of the elements to bring the elements to a set of operating parameters, such as magnification and position of the charged particle beam at the EELS spectrometer, or magnification and width of the dispersed charged particle beam at the detector. In the context of the present disclosure, operation 305 can include the same or similar sub-operations applied to shift the calibration energy of the elements from a first energy (e.g., E1 of FIG. 2) to a second energy (e.g., E2 of FIG. 2). In this way, operation 305 can include recalibrating the elements 220 for a higher energy, recalibrating the elements 230, 235, and 240 for a lower energy, or both. In this context, the term “calibration energy” refers to a set of operating parameter(s) that configures the charged particle optical elements to apply an appropriate force on a beam of charged particles (e.g., beam of charged particles 215 of FIG. 2). As electrostatic elements can apply a refractive effect that is inversely proportional to the energy of the beam (ignoring relativistic effects) and magnetic elements can apply a refractive effect that is inversely proportional to the square root of the energy of the beam multiplied by the particle's velocity (ignoring relativistic effects), mis-calibrated elements can exhibit impaired performance for a given energy of the beam. In an illustrative example where the optical element is a condenser lens, a beam of electrons can be underfocused or overfocused by about 100 nanometer when the lens is mis-calibrated by as little as 10 eV.

At operation 305, the shifting of the calibration from a first energy (e.g., E1) to a second energy (e.g., E2) can be performed using energy-scaling-behavior of the charged partical optical elements. For example, a magnetic multipole element can be recalibrated from energy E1 to energy E2 by scaling its known calibration at E1 by a factor √(E1/E2) (ignoring relativistic effects). As part of such scaling of the calibration, magnetic elements can be operated, configured, or otherwise conditioned to be substantially free of magnetic saturation and hysteresis. Scaling can also be applied to beam deflectors and beam stigmators, where the mechanical alignment of the optical elements can be improved in this way.

In conventional EELS mode, the optical elements 220, 230, 235, and 240 can be calibrated for a beam energy of about 300 keV, generated by the source of charged particles 205. As part of transitioning from conventional EELS mode to high-loss EELS mode, operation 305 can include recalibrating elements 220 from an energy of about 300 keV to an energy of about 310 keV, with a commensurate increase of the corresponding beam energy via modifying the operating parameters of the source of charged particles 205. In some embodiments, operation 305 can include recalibrating elements 230, 235, and 240 from an energy of about 300 keV to an energy of about 290 keV. In this way, a portion of the electrons of the beam of charged particles 215 that transfer about 10 keV to the sample 225 can be focused onto the detector 245.

At operation 310, example process 300 includes generating a beam of charged particles. In the example of a transmission electron microscope (TEM), operation 310 can include applying a voltage to an electron emitter (e.g., source of charged particles 205 of FIG. 2), in accordance with a set of parameters that will result in the beam of charged particles having an energy about the first energy. In the example above, where the first energy is about 300 keV and the second energy is about 290 keV, operation 310 includes generating a beam of charged particles having an energy of about 300 keV.

At operation 315, example process 300 includes generating detector data. Detector data can include EELS data generated by coupling the beam of electrons (e.g., beam of charged particles 215 of FIG. 2) into an EELS spectrometer (e.g., EELS spectrometer 115 of FIG. 1). A result of operation 305 can be that the portion of the beam of electrons having an energy about the second energy are directed toward the detector (e.g., detector 245 of FIG. 2) and the portion of the beam of electrons scattered by an energy different from the second energy by an extent greater than about 0.02. E2 are blocked or otherwise redirected away from the detector 245, either by the microscope (e.g., the TEM column 105 of FIG. 1 and the microscope 201 of FIG. 2) or by components of the spectrometer (e.g., energy dispersive filter 235).

In some embodiments, one or more operations of example process 300 can be repeated in one or more iterations as part of generating a dataset of EELS spectra for a given sample or for multiple samples. For example, operations 305-315 can be repeated over a range of second energy values for a given first energy value. In this way, the difference between the first energy and the second energy can be varied over a range, for example, as part of a characterization of a sample to detect and identify elements present in the sample (e.g., by measuring inner shell ionization edges in EELS data at multiple energies). In another example, operation 315 can be repeated at multiple points on a sample surface, as part of generating an EELS datacube mapping out chemical and/or physical data for the sample. In this context, a “datacube” refers to a hierarchical data structure in which EELS data are referenced to one or more pixels of an image of a sample surface, as part of “mapping” the surface of the sample (e.g., with elemental information).

Advantageously, the presence of fine-structure in EELS data generated using the techniques described herein permits localized structural information to be derived, for example, by fitting one or more models to the detector data from which bonding information, oxidation state, or other physical and/or chemical properties of the sample can be derived. Analogous models used for extended x-ray absorption fine structure (EXAFS) analysis can be used to determine interatomic spacings (e.g., using EXELFS models), oxidation state, band structure, and/or coordination information (e.g., crystal structure, bonding, or the like). As the spatial resolution of EELS systems in STEM mode can be on the order of single atoms, EELS data generated using example process 300 can be used to map chemical, physical, and/or structural information over a region of a sample surface.

FIG. 4A is a graph illustrating example electron energy loss spectrum (EELS) data 400 and Extended X-ray Absorption Fine-Structure (EXAFS) data 405 for a molybdenum foil sample, in accordance with some embodiments of the present disclosure. The graph includes data for an inner shell ionization that is represented as an edge centered about 20 keV including fine structure. The graph plots the data 400 and 405 on a two-dimensional set of axes, with energy on the ordinate, over a range from about 19.95 keV to about 20.25 keV, and counts on the abscissa in arbitrary units (AU). The abscissa is presented without numerals, because the data 400 and 405 are respectively normalized as a result of different data generation modalities. Advantageously, such treatment emphasizes the correspondence of the edge position and fine structure in common between the data types. In the example data shown, the EELS data 400 reproduce the positions of features of the fine structure present in EXAFS data. In comparison, current techniques for measuring EELS data at similarly high energy losses typically result in significant signal-to-noise limitations because of mis-calibration of the solid angle collected by the EELS spectrometer (leading to inadequate collection angles), and to the introduction of aberrations in the TEM column and in the EELS spectrometer that negatively affect data quality, such as energy resolution. In accordance with the techniques described herein, such mis-calibrations and such aberrations are significantly reduced or removed, providing significant improvement to signal-to-noise characteristics of detector data and significant improvement of energy resolution, which together greatly facilitate EXELFS analysis.

FIG. 4B is a graph illustrating example electron energy loss spectrum (EELS) data 410 for an antimony (Sb) sample, in accordance with some embodiments of the present disclosure. The data present an EELS spectrum for the K-edge of antimony at about 30.5 keV. The data 410 were acquired in 782 seconds with 20 nA beam current, corresponding to a dose of about 15.5 μC. The data 410 are presented to further illustrate energy loss values addressed by embodiments of the present disclosure. The counts values presented on the abscissa illustrate the improvement to signal-to-noise characteristics of relatively high energy loss edges, reinforcing the demonstration in FIG. 4A that includes fine structure from which physical structure information can be derived.

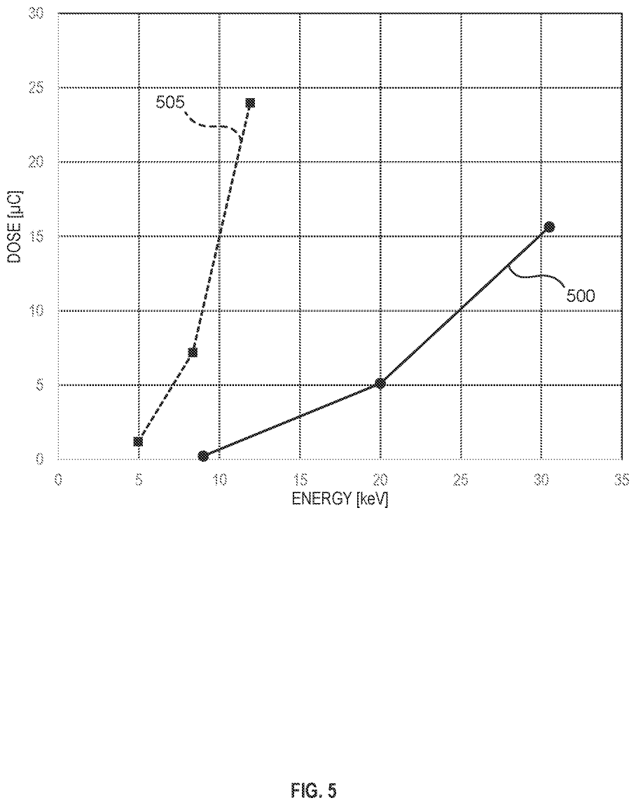

FIG. 5 is a graph illustrating example electron dose data for different material samples used to collect EELS data for embodiments of the present disclosure 500 and comparative techniques of the present art 505. The graph of FIG. 5 presents shell energy in keV on the ordinate and dose in microcoulombs (uC) on the abscissa. The data 500 were generated in a TEM using the techniques described in reference to FIGS. 1-4B. In comparison, data 505 are presented using a different technique reported in the art that described “a customized lens configuration to improve signal collection and reduce high energy artifacts,” which corresponds to varying the collection semi-angle from 73 milliradians (mR) at 5 keV energy loss to 56 mR at 10 keV energy loss. This contrasts with the techniques described herein that include modifying the parameters of the charged particle optical elements of a charged particle microscope system, as described in more detail in reference to FIGS. 1-4B. FIG. 5 also demonstrates the expanded range of energy values over which the techniques described herein can be applied.

The data 505 of the current art are characterized by significantly higher electron doses used to generate extended energy loss fine spectrum (EXELFS) data with suitable signal-to-noise characteristics. In an illustrative example, the data 500 generated in accordance with embodiments of the present disclosure generated a suitable EXELFS spectrum for a copper edge at 9 keV with a probe current of 2.3 nA, a total integration time of 100 seconds, and a total electron dose of about 0.23 μC. In contrast, the data 505 of the current art reported, for a Ni edge at 8.35 keV, a probe current of 6 nA, an integration time of 1200 seconds, and a total electron dose of 7.2 μC, a 31-fold increase relative to the data 500 of the present disclosure.

In general, the data 505 reported an increase in total electron dose from 1.2 μC to 24 μC for edge energies from 4.96 keV to 11.92 keV. In comparison, data 500 of the present disclosure range from 0.23 μC at 9 keV to 5.12 μC at 20 keV (corresponding to the molybdenum edge described in reference to FIG. 4A), to 15.64 μC AT 30.4 keV (corresponding to the antimony k-edge described in reference to FIG. 4B). For dose-sensitive samples, where the energy of the beam of electrons can change the chemical, physical, and/or structural properties of the samples, reduced electron dose represents a significant improvement and makes the technique significantly more applicable for microanalysis. Advantageously, reduction of the electron dose permits higher beam energies (e.g., E1 of FIG. 2) to be employed, further improving signal-to-noise characteristics of EXELFS data.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on electron microscopy systems, and scanning transmission electron microscopy systems in particular, these are meant as non-limiting, illustrative embodiments. Embodiments of the present disclosure are not limited to such embodiments, but rather are intended to address analytical instruments systems for which a wide array of material samples can be analyzed to determine chemical, biological, physical, structural, or other properties, among other aspects, including but not limited to chemical structure, trace element composition, or the like. As such, embodiments of the present disclosure include charged particle instruments more broadly, including focused ion beam systems, scanning electron microscope systems, electron beam microanalysis systems, or the like.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For numerical values, such as dimensions (e.g., diameters, lengths, widths, or the like) and energies, the term “about” can be understood to describe a deviation from the stated value of up to ±30%. For example, a dimension of “about 10 mm” can describe a dimension from 7 mm to 13 mm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. A charged particle microscope system, comprising:
a beam column section, comprising:
one or more charged particle optical elements calibrated for a first energy; and
one or more charged particle optical elements calibrated for a second energy; and
a detector section, disposed at a position downstream of the beam column section and comprising an electrostatic or magnetic prism and one or more charged particle optical elements calibrated for the second energy,
wherein the first energy and the second energy are different.

2. The charged particle microscope system of claim 1, wherein:
the beam column section further comprises a sample section;
the one or more charged particle optical elements calibrated for the first energy are upstream of a sample disposed in the sample section, relative to a charged particle source; and
the one or more charged particle optical elements of the beam column calibrated for the second energy are disposed downstream of the sample section.

3. The charged particle microscope system of claim 1, wherein the sample section includes an objective lens, and wherein the sample is immersed in an objective field of the objective lens.

4. The charged particle microscope system of claim 1, wherein the detector section comprises an EELS spectrometer, calibrated to detect charged particles having an energy about the second energy, based at least in part on energy transfer with inner shell electrons in a sample.

5. The charged particle microscope system of claim 1, wherein a difference between the first energy and the second energy is from about 2 keV to about 50 keV.

6. The charged particle microscope system of claim 5, wherein the second energy is from about 90% to about 97.5% of the first energy.

7. The charged particle microscope system of claim 1, wherein:
the first energy and the second energy are related by the expression A=|(ΔE+E2−E1)/E2|, where ΔE is the energy loss associated with an edge (keV), E1 is the first energy (keV), and E2 is the second energy (keV); and
the expression A is less than or equal to about 5%.

8. The charged particle microscope system of claim 1, wherein the first energy is about 300 keV and the second energy is from about 270 keV to about 295 keV.

9. The charged particle microscope system of claim 1, further comprising:
control circuitry, operably coupled with the beam column section and the detector section; and
one or more non-transitory machine-readable storage media, storing machine executable instructions that, when executed by the control circuitry, cause the charged particle microscope system to perform operations comprising:
generating a beam of charged particles at the first energy; and
generating detector data using the detector section, the detector data describing charged particles at about the second energy.

10. The charged particle microscope system of claim 1, wherein:
a calibration scheme for the first energy comprises a first set of operating parameters;
a calibration scheme for the second energy comprises a second set of operating parameters; and
the first set of operating parameters and the second set of operating parameters are related by a scaling factor based at least in part on the energy dependence of refractive effects of the optical elements calibrated for the second energy.

11. One or more non-transitory machine-readable storage media storing instructions that, when executed by a machine, cause the machine to perform operations comprising:
recalibrating one or more charged particle optical elements of a charged particle microscope system from a first energy to a second energy, such that the charged particle microscope system comprises:
a beam column section, comprising:
one or more charged particle optical elements calibrated for the first energy; and
one or more charged particle optical elements calibrated for the second energy; and
a detector section, disposed at a position downstream of the beam column section and comprising a magnetic or electrostatic prism and one or more charged particle optical elements calibrated for the second energy,
wherein the first energy and the second energy are different.

12. The media of claim 11, wherein the operations further comprise:
generating a beam of charged particles at the first energy; and
generating detector data using the detector section, the detector data describing charged particles at about the second energy.

13. The media of claim 12, wherein the detector data comprise electron energy loss spectrum (EELS) data.

14. The media of claim 12, wherein the operations further comprise determining an interatomic spacing parameter of a sample using the detector data.

15. The media of claim 11, wherein recalibrating the one or more charged particle optical elements calibrated from the first energy to the second energy comprises:
measuring the collection angle of the EELS spectrometer; or
centering the beam with respect to the EELS spectrometer.

16. The media of claim 11, wherein the operations further comprise:
recalibrating the charged particle optical elements calibrated for the first energy from the first energy to the second energy;
generating a beam of charged particles at the second energy; and
generating detector data using the detector section, the detector data describing charged particles at about the second energy.

17. The media of claim 11, wherein the operations further comprise:
receiving user interaction data via an interactive user interface, the interaction data corresponding to an action by a user to initiate recalibration of the one or more elements of the charged particle microscope system.

18. The media of claim 16, wherein the operations further comprise:
generating user interface data configured to modify a display being operably coupled with the charged particle microscope system to present the interactive user interface.

19. The media of claim 11, wherein a difference between the first energy and the second energy is from about 2 keV to about 50 keV.

20. The media of claim 11, wherein the second energy is from about 90% to about 97.5% of the first energy.
